(19) United States
(12) Patent Application Publication
(10) Pub. No.: US 2026/0213643 A1
(43) Pub. Date: Jul. 23, 2026

(54) GALLIUM NITRIDE SWITCHING CIRCUIT AND DRIVING CIRCUIT FOR GALLIUM NITRIDE SWITCHING CIRCUIT

(71) Applicant: SUZHOU NOVOSENSE MICROELECTRONICS CO., LTD., Suzhou (CN)

(72) Inventors: Linzhen LI, Suzhou (CN); Xiaowen JIANG, Suzhou (CN); Jiandong LIU, Suzhou (CN)

(21) Appl. No.: 19/298,233

(22) Filed: Aug. 13, 2025

(30) Foreign Application Priority Data
Jan. 10, 2025 (CN) 202510039852.X

(51) Int. Cl. H02M 1/088; H02M 3/158

(52) U.S. Cl. CPC H02M 1/088; H02M 3/158

(57) ABSTRACT

A gallium nitride switching circuit and a driving circuit for the same are disclosed, the gallium nitride switching circuit has a high-side gallium nitride switch and a low-side gallium nitride switch. The driving circuit has a first switching transistor, a second switching transistor and a capacitor. The first switching transistor has a first terminal receiving a power supply voltage, a control terminal receiving a first control signal. The second switching transistor has a first terminal coupled to the second terminal of the first switching transistor, a control terminal receiving a second control signal. The capacitor has a first terminal coupled to the second terminal of the second switching transistor, a second terminal coupled to a common terminal of the high-side gallium nitride switch and the low-side gallium nitride switch.

### CROSS-REFERENCE TO RELATED APPLICATIONS

The present application claims priority to and the benefit of Chinese Patent Application No. 202510039852.X, filed on Jan. 10, 2025, the disclosures of which is incorporated herein by reference in its entirety.

### TECHNICAL FIELD

The present application relates to the technical field of driving circuits, and in particular to a gallium nitride switching circuit and a driving circuit for the gallium nitride switching circuit.

### BACKGROUND

Compared with metal-oxide-semiconductor field-effect transistors (MOSFETs), gallium nitride field-effect transistors (GaN FETs) feature faster switching speeds and lower switching losses, and are suitable for system applications with high switching frequencies. In power supply systems, the use of GaN FETs, on one hand, can significantly optimize the volume and weight of magnetic components due to the increased switching frequency, thereby contributing to the reduction of system volume and weight. On the other hand, in power supply systems with the same switching frequency, the use of GaN FETs also helps improve system efficiency.

Another significant advantage of GaN FETs lies in the absence of an intrinsic body diode between the source and the drain. The elimination of the intrinsic body diode removes the reverse recovery losses associated with the intrinsic body diode, enabling further efficiency improvements in systems when GaN FETs are used in half-bridge circuits.

However, despite the outstanding performance advantages of GaN FETs over MOSFETs, the sensitive gate structures of GaN FETs pose higher requirements for practical applications. When the gate driving voltage is too high, it may affect the device lifespan and even pose a risk of gate breakdown. Therefore, there is a need for a driving circuit that can address the issue of reduced circuit reliability caused by excessively high gate driving voltages in gallium nitride transistors.

### SUMMARY

The present application provides a gallium nitride switching circuit and a driving circuit for the gallium nitride switching circuit, aiming to solve the problem that the gate of a gallium nitride transistor is prone to damage when the gate driving voltage of the gallium nitride transistor is excessively high.

According to a first aspect of the present application, the present application provides a driving circuit for a gallium nitride switching circuit. The gallium nitride switching circuit includes a high-side gallium nitride switch and a low-side gallium nitride switch, and power voltage conversion is realized by controlling on and off of the high-side gallium nitride switch and the low-side gallium nitride switch. The driving circuit includes: a first switching transistor, having a first terminal, a second terminal, and a control terminal, where the first terminal of the first switching transistor is configured to receive a power supply voltage, the control terminal of the first switching transistor is configured to receive a first control signal, and the first switching transistor is turned on or turned off based on the first control signal; a second switching transistor, having a first terminal, a second terminal, and a control terminal, where the first terminal of the second switching transistor is coupled to the second terminal of the first switching transistor, the control terminal of the second switching transistor is configured to receive a second control signal, and the second switching transistor is turned on or turned off based on the second control signal; and a capacitor, having a first terminal and a second terminal, where the first terminal of the capacitor is coupled to the second terminal of the second switching transistor, the second terminal of the capacitor is coupled to a common terminal of the high-side gallium nitride switch and the low-side gallium nitride switch, and a voltage at the common terminal of the high-side gallium nitride switch and the low-side gallium nitride switch is a switching node voltage; where when the low-side gallium nitride switch is turned off, the first switching transistor is turned off, when the low-side gallium nitride switch is turned on, the first switching transistor is turned on; and when the low-side gallium nitride switch is turned on and the switching node voltage is less than a reference voltage, the second switching transistor is turned on.

According to a second aspect of the present application, the present application provides a gallium nitride switching circuit, including the driving circuit according to any of the above first aspect, and further including: a high-side gallium nitride switch, having a source terminal, a drain terminal, and a gate terminal; a low-side gallium nitride switch, having a source terminal, a drain terminal, and a gate terminal, where a drain terminal of the low-side gallium nitride switch is coupled to a source terminal of the high-side gallium nitride switch; and an inductor, where one terminal of the inductor is coupled to a common terminal of the high-side gallium nitride switch and the low-side gallium nitride switch.

Through one or more of the above embodiments of the present application, at least the following technical effects can be achieved.

The present application controls the charging time of the capacitor by controlling the conduction status of the first switching transistor and the second switching transistor connected in series in the charging loop of the capacitor, effectively solving the problem of capacitor overcharging in a half-bridge circuit operating in Buck mode and protecting the gate of the high-side gallium nitride transistor. Meanwhile, the conduction and cutoff of the charging path are controlled according to the reference voltage, thereby preventing reverse feeding of the charging voltage on the capacitor to the power supply voltage and improving the reliability of the driving circuit.

### BRIEF DESCRIPTION OF THE DRAWINGS

To more clearly illustrate the technical solutions in the embodiments of the present application, the drawings required for describing the embodiments will be briefly introduced below. Obviously, the drawings in the following description are merely some embodiments of the present application, and those skilled in the art can obtain other drawings based on these drawings without exerting creative efforts.

FIG. 1 is a schematic structural diagram of an existing driving circuit for a gallium nitride switching circuit;

FIG. 2 is a schematic circuit structural diagram of a driving circuit for a gallium nitride switching circuit according to an embodiment of the present application;

FIG. 3 is a schematic circuit structural diagram of a charging control circuit according to an embodiment of the present application;

FIG. 4 is a schematic circuit diagram of a buck gallium nitride switching circuit according to an embodiment of the present application;

FIG. 5 is a waveform diagram of various signals in the buck gallium nitride switching circuit shown in FIG. 4;

FIG. 6 is a circuit schematic diagram of a boost gallium nitride switching circuit according to an embodiment of the present application;

FIG. 7 is a waveform diagram of various signals in the boost gallium nitride switching circuit shown in FIG. 6.

### DETAILED DESCRIPTION

The technical solutions in the embodiments of the present application will be clearly and completely described below with reference to the drawings in the embodiments of the present application. Obviously, the described embodiments are only a part of the embodiments of the present application, rather than all the embodiments. Based on the embodiments in the present application, all other embodiments obtained by those skilled in the art without creative labor shall fall within the protection scope of the present application.

It should be noted that the terms “first”, “second” and the like in the description and claims of the present application and the above drawings are used to distinguish similar objects, and are not necessarily used to describe a specific order or sequence. It should be understood that the data used in this way can be interchanged under appropriate circumstances so that the embodiments of the present application described herein can be implemented in an order other than those illustrated or described herein. In addition, the terms “comprise” and “have” and any variations thereof are intended to cover non-exclusive inclusion. For example, a process, method, system, product or device including a series of steps or units is not necessarily limited to those steps or units clearly listed, but may include other steps or units not clearly listed or inherent to such processes, methods, products or devices.

It should be understood that in the following description, a “circuit” refers to a conductive loop formed by at least one component or sub-circuit through electrical connection or electromagnetic connection. When a component or circuit is said to be “connected to” another component or a component/circuit is said to be “connected between” two nodes, it can be directly coupled or connected to the other component, or there may be intermediate components, and the connection between components may be physical, logical, or a combination thereof. In contrast, when a component is said to be “directly coupled to” or “directly connected to” another component, it means that there are no intermediate components between the two.

FIG. 1 is a schematic structural diagram of an existing driving circuit for a gallium nitride switching circuit. The gallium nitride switching circuit includes a high-side gallium nitride switch Q1 and a low-side gallium nitride switch Q2 connected in series. A power supply voltage VDD supplies power to a low-side gate driver 160, the power supply voltage VDD is generally 5V, and an output of the low-side gate driver 160 is connected to a gate of the low-side gallium nitride switch Q2. An output of a high-side gate driver 150 is connected to a gate of the high-side gallium nitride switch Q1, and the power supply voltage VDD supplies power to the high-side gate driver 150 through the driving circuit. The driving circuit in FIG. 1 includes a capacitor 170 and a diode 180, the power supply voltage VDD is coupled to an anode of the diode 180, a cathode of the diode 180 is connected to one terminal of the capacitor 170, and the other terminal of the capacitor 170 is connected to a switching node SW. A power supply level of the high-side gate driver 150 is generated by the driving circuit. When the low-side gallium nitride switch Q2 is turned on, a voltage of the switching node SW is pulled to a low level, the power supply voltage VDD charges the capacitor 170 through the diode 180; when the voltage of the switching node SW is pulled to a high level, the diode 180 is reversely cut off, and the charging path is blocked.

In the driving circuit of the gallium nitride switching circuit shown in FIG. 1, dead time is set to prevent the high-side gallium nitride switch Q1 and the low-side gallium nitride switch Q2 from being turned on at the same time. During the dead time, a high-side driving signal V_{GS_H} and a low-side driving signal V_{GS_L} are at a low level, and the high-side gallium nitride switch Q1 and the low-side gallium nitride switch Q2 are turned off at the same time. During the dead time, since an inductor current on an inductor 140 cannot change suddenly, freewheeling would be conducted through the low-side gallium nitride switch Q2. After a channel of the low-side gallium nitride switch Q2 is reversely conducted, the voltage of the switching node SW is clamped to a negative voltage that can maintain the inductor current, generally around −2V. The capacitor 170 is charged during the conduction period of the low-side gallium nitride switch Q2, and a charging voltage on the capacitor 170 is a voltage difference between the power supply voltage VDD and the voltage of the switching node SW. Since the switching node voltage SW is a negative voltage (around −2V), if the power supply voltage VDD is 5V, the charging voltage on the capacitor C may reach more than 7V, which will damage the gate of the high-side gallium nitride switch Q1.

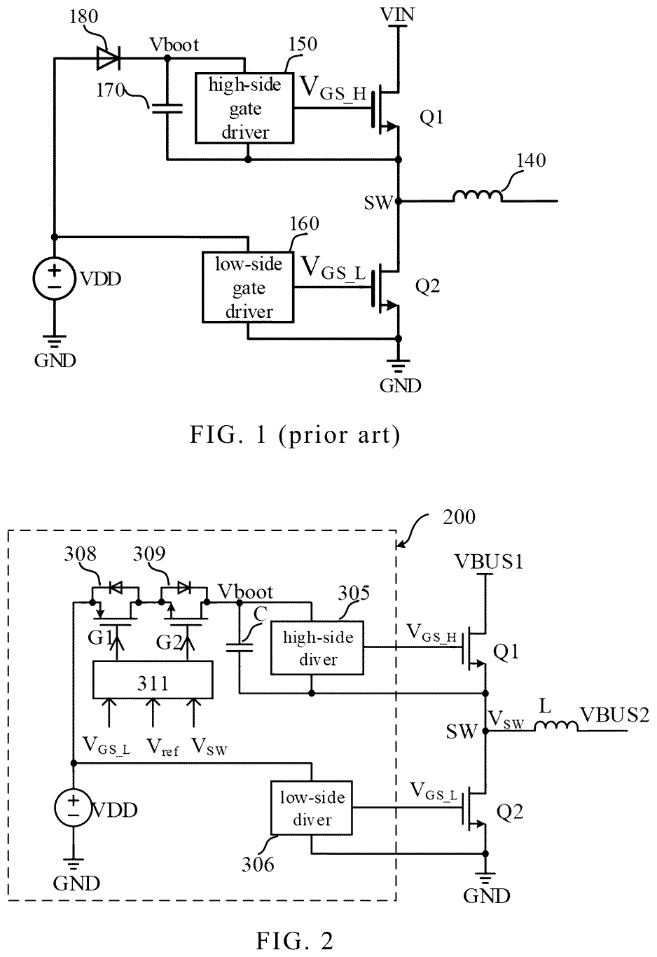

FIG. 2 is a schematic circuit structural diagram of a driving circuit for a gallium nitride switching circuit according to an embodiment of the present application. The gallium nitride switching circuit includes a high-side gallium nitride switch Q1 and a low-side gallium nitride switch Q2, and an input voltage is converted into an output voltage by controlling on and off of the high-side gallium nitride switch Q1 and the low-side gallium nitride switch Q2. In the embodiment shown in FIG. 2, both the low-side gallium nitride switch Q2 and the high-side gallium nitride switch Q1 are N-type switching transistors, the low-side gallium nitride switch Q2 is turned on or turned off under control of a low-side driving signal V_{GS_L}, and the high-side gallium nitride switch Q1 is turned on or turned off under control of a high-side driving signal V_{GS_H}. When the high-side driving signal V_{GS_H} is at a low level, the high-side gallium nitride switch Q1 is turned off; and when the high-side driving signal V_{GS_H} is at a high level, the high-side gallium nitride switch Q1 is turned on. When the low-side driving signal V_{GS_L} is at a low level, the low-side gallium nitride switch Q2 is turned off; and when the low-side driving signal V_{GS_L} is at a high level, the low-side gallium nitride switch Q2 is turned on. In the embodiment shown in FIG. 2, the input voltage may be a first bus voltage VBUS1, and the output voltage may be a second bus voltage VBUS2, that is, the gallium nitride switching circuit converts the first bus voltage VBUS1 into the second bus voltage VBUS2, where the second bus voltage VBUS2 is less than the first bus voltage VBUS1. The input voltage may also be the second bus voltage VBUS2, and the output voltage is the first bus voltage VBUS1, that is, the gallium nitride switching circuit converts the second bus voltage VBUS2 into the first bus voltage VBUS1, where the first bus voltage VBUS1 is greater than the second bus voltage VBUS2. The driving circuit 200 includes a first switching transistor 308, a second switching transistor 309, and a capacitor C. The first switching transistor 308 has a first terminal, a second terminal, and a control terminal, where the first terminal of the first switching transistor 308 receives a power supply voltage VDD, the control terminal of the first switching transistor 308 receives a first control signal G1, and the first switching transistor 308 is turned on or turned off based on the first control signal G1. The second switching transistor 309 has a first terminal, a second terminal, and a control terminal, where the first terminal of the second switching transistor 309 is coupled to the second terminal of the first switching transistor 308, the control terminal of the second switching transistor 309 receives a second control signal G2, and the second switching transistor 309 is turned on or turned off based on the second control signal G2. The capacitor C has a first terminal and a second terminal, where the first terminal of the capacitor C is coupled to the second terminal of the second switching transistor 309, the second terminal of the capacitor C is coupled to a common node SW of the high-side gallium nitride switch Q1 and the low-side gallium nitride switch Q2, and a voltage at the common node SW of the high-side gallium nitride switch Q1 and the low-side gallium nitride switch Q2 is a switching node voltage V_{SW}. When the low-side driving signal V_{GS_L} is at a low level, that is, when the low-side gallium nitride switch Q2 is turned off, the first switching transistor 308 is turned off; when the low-side driving signal V_{GS_L} is at a high level, that is, when the low-side gallium nitride switch Q2 is turned on, the first switching transistor 308 is turned on. When the low-side driving signal V_{GS_L} is at a high level and the switching node voltage V_{SW} is less than a reference voltage V_{ref}, the second switching transistor 309 is turned on. In an embodiment, the power supply voltage VDD and the driving circuit 200 are integrated in the same chip. In another embodiment, the power supply voltage VDD is an external power supply, providing an operation power supply for the driving circuit 200. In some embodiments, the reference voltage V_{ref} is in a range from 2V to 3V.

In the embodiment shown in FIG. 2, the first switching transistor 308 is a P-type field-effect transistor, and the second switching transistor 309 is an N-type field-effect transistor. It should be noted that, in an embodiment, the first field-effect transistor 308 is a P-type gallium nitride field-effect transistor, and the second field-effect transistor 309 is an N-type gallium nitride field-effect transistor. In an embodiment, the first field-effect transistor 308 and the second field-effect transistor 309 are integrated in the same chip as the driving circuit 200. In an embodiment, the first field-effect transistor 308 and the second field-effect transistor 309 are discrete devices. In the embodiment shown in FIG. 2, when the low-side driving signal V_{GS_L} is at a low level, that is, when the low-side gallium nitride switch Q2 is turned off, the first control signal G1 is at a high level, and the first switching transistor 308 is turned off. When the low-side driving signal V_{GS_L} is at a high level, that is, when the low-side gallium nitride switch Q2 is turned on, the first control signal G1 is at a low level, and the first switching transistor 308 is turned on. When the low-side driving signal V_{GS_L} is at a high level and the switching node voltage V_{SW} is less than the reference voltage V_{ref}, the second control signal G2 is at a high level, and the second switching transistor 309 is turned on.

The driving circuit 200 further includes a charging control circuit 311. The charging control circuit 311 receives the reference voltage V_{ref}, the switching node voltage V_{SW}, and the low-side driving signal V_{GS_L}, and generates the first control signal G1 and the second control signal G2 according to the reference voltage V_{ref}, the switching node voltage V_{SW}, and the low-side driving signal V_{GS_L} to respectively control on and off of the first switching transistor 308 and the second switching transistor 309. Exemplarily, when the low-side driving signal V_{GS_L} is at a low level, the low-side gallium nitride switch Q2 is turned off, the first control signal G1 is at a high level, and the first switching transistor 308 is turned off. When the low-side driving signal V_{GS_L} is at a high level, the low-side gallium nitride switch Q2 is turned on, the first control signal G1 is at a low level, and the first switching transistor 308 is turned on. When the low-side driving signal V_{GS_L} is at a high level and the switching node voltage V_{SW} is less than the reference voltage V_{ref}, the low-side gallium nitride switch Q2 is turned on, the second control signal G2 is at a high level, and the second switching transistor 309 is turned on.

The gallium nitride switching circuit shown in FIG. 2 may be a buck circuit or a boost circuit according to different application scenarios. For example, when the gallium nitride switching circuit is applied to a buck requirement, that is, the gallium nitride switching circuit is a buck switching circuit, the gallium nitride switching circuit converts the first bus voltage VBUS1 into the second bus voltage VBUS2, where a value of the second bus voltage VBUS2 is less than a value of the first bus voltage VBUS1. When the gallium nitride switching circuit is applied to a boost requirement, that is, the gallium nitride switching circuit is a boost switching circuit, the gallium nitride switching circuit converts the second bus voltage VBUS2 into the first bus voltage VBUS1, where a value of the first bus voltage VBUS1 is greater than a value of the second bus voltage VBUS2. It should be noted that the driving circuit protected by the present application is applicable to any switching circuit including gallium nitride switches, including but not limited to full-bridge circuits or half-bridge circuits such as BUCK, BOOST, and LLC.

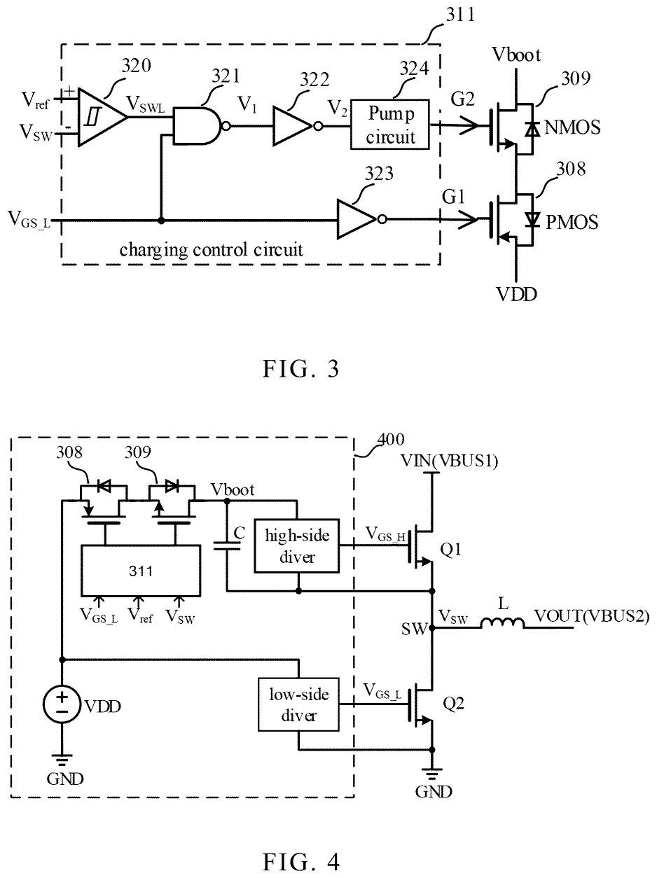

FIG. 3 is a schematic circuit structural diagram of the charging control circuit 311 according to an embodiment of the present application. The charging control circuit 311 includes a comparison circuit 320, a logic circuit 321, a first inverter 322, and a second inverter 323. The comparison circuit 320 has a first input terminal receiving the reference voltage V_{ref}, a second input terminal receiving the switching node voltage V_{SW}, and an output terminal providing a comparison signal V_{SWL}, and the comparison circuit 320 generates the comparison signal V_{SWL} according to the reference voltage V_{ref} and the switching node voltage V_{SW}. The logic circuit 321 has a first input terminal receiving the comparison signal V_{SWL} and a second input terminal receiving the low-side driving signal V_{GS_L}, and the logic circuit 321 generates a first signal V₁ according to the comparison signal V_{SWL} and the low-side driving signal V_{GS_L}. The first inverter 322 has an input terminal receiving the first signal V₁ and an output terminal providing a control signal V₂, where the control signal V₂ and the second control signal G2 only differ in amplitude and have the same phase. The second inverter 323 has an input terminal receiving the low-side driving signal V_{GS_L}, and an output terminal providing the first control signal G1. The operation principle of the charging control circuit 311 is as follows: when the switching node voltage V_{SW} is less than the reference voltage V_{ref}, the comparison signal V_{SWL} is at a high level; and when the switching node voltage V_{SW} is greater than the reference voltage V_{ref}, the comparison signal V_{SWL} is at a low level. When both the comparison signal V_{SWL} and the low-side driving signal V_{GS_L} are at a high level, the first signal V₁ is at a low level; and when the comparison signal V_{SWL} and/or the low-side driving signal V_{GS_L} is at a low level, the first signal V₁ is at a high level. The second control signal G2 is inverted to the first signal V₁, and the first control signal G1 is inverted to the low-side driving signal V_{GS_L}. In the embodiment shown in FIG. 3, the charging control circuit 311 may further include a Pump circuit 324 for boosting the control signal V₂ output by the first inverter 322 to form the second control signal G2 to drive the second switching transistor 309, that is, the control signal V₂ and the second control signal G2 only differ in amplitude and have the same phase.

FIG. 4 is a circuit schematic diagram of a buck gallium nitride switching circuit according to an embodiment of the present application. In the embodiment shown in FIG. 4, an output voltage VOUT is less than an input voltage VIN, a tolerance voltage of the first switching transistor 308 is in a range from 5V to 10V, and a tolerance voltage of the second switching transistor 309 is greater than the input voltage VIN (the first bus voltage VBUS1). In the embodiment shown in FIG. 4, the first switching transistor 308 is turned on and turned off synchronously with the low-side gallium nitride switch Q2, that is, when the low-side gallium nitride switch Q2 is turned on, the first switching transistor 308 is turned on; when the low-side gallium nitride switch Q2 is turned off, the first switching transistor 308 is turned off, the power supply voltage VDD cannot charge the capacitor C, and the charging path is turned off. Therefore, the problem of gate breakdown of the high-side gallium nitride switch Q1 caused by excessive charging voltage on the capacitor C due to freewheeling of the low-side gallium nitride switch Q2 through reverse channel conducting during the dead time in the existing driving circuit is solved.

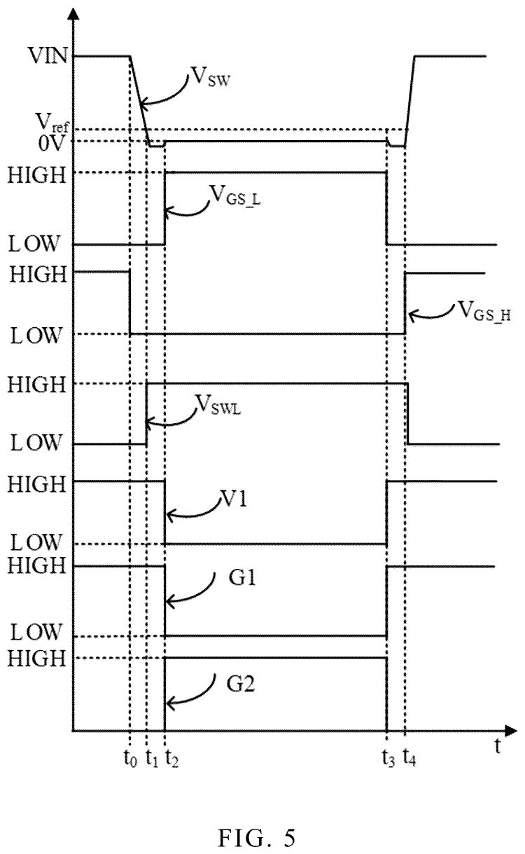

FIG. 5 is a waveform diagram of various signals in the buck gallium nitride switching circuit shown in FIG. 4. The waveforms of various signals in FIG. 5 are explained with reference to the buck gallium nitride switching circuit shown in FIG. 4. Before time to, the low-side driving signal V_{GS_L} is at a low level, the low-side gallium nitride switch Q2 remains turned off, the high-side driving signal V_{GS_H} drives the high-side gallium nitride switch Q1 to remain conducting, and the switching node voltage V_{SW} is the input voltage VIN in the case that the on-voltage when the high-side gallium nitride switch Q1 is conducting is ignored. The first control signal G1 is at a high level, the first switching transistor 308 is turned off, the second control signal G2 is at a low level, and the second switching transistor 309 is turned off.

At time t0, the high-side driving signal V_{GS_H} switches from high level to low level, the high-side gallium nitride switch Q1 is turned off, the switching node voltage V_{SW} drops rapidly, and the buck gallium nitride switching circuit enters the dead time.

At time t1, the switching node voltage V_{SW} drops to less than the reference voltage V_{ref}, and the comparison signal V_{SWL} switches from low level to high level. The low-side driving signal V_{GS_L} remains at a low level, the first switching transistor 308 remains turned off, and the second switching transistor 309 is turned off. During this period, the reverse channel of the low-side gallium nitride switch Q2 is turned on to freewheel for the inductor L, and the switching node voltage V_{SW} continues to decrease to a negative voltage.

At time t2, the low-side driving signal V_{GS_L} switches to high level, the low-side gallium nitride switch Q2 is turned on, and the switching node voltage V_{SW} is close to zero voltage at this time; the first control signal G1 switches to low level, the first switching transistor 308 is turned on, and since the switching node voltage V_{SW} is less than the reference voltage V_{ref} at this time, both the comparison signal V_{SWL} and the low-side driving signal V_{GS_L} are at high level, the first signal V₁ is at low level, the second control signal G2 switches to high level, and the second switching transistor 309 is turned on. After both the first switching transistor 308 and the second switching transistor 309 are turned on, the power supply voltage VDD charges the capacitor C through channels of the first switching transistor 308 and the second switching transistor 309, and the high-side voltage Vboot is close to the value of the power supply voltage VDD.

At time t3, the low-side driving signal V_{GS_L} switches from high level to low level, and the low-side gallium nitride switch Q2 is turned off. The first control signal G1 switches to high level, the first switching transistor 308 is turned off, and the charging path is blocked. The first signal V₁ switches to high level, the second control signal G2 is at low level, and the second switching transistor 309 is turned off. Then, during the dead time, the reverse channel of the low-side gallium nitride switch Q2 is turned on to freewheel the inductor current, and the switching node voltage Vsw decreases to a negative voltage.

At time t4, the low-side driving signal V_{GS_L} remains at low level, the first control signal G1 is at high level, the first switching transistor 308 remains turned off, the second control signal G2 is at low level, the second switching transistor 309 remains turned off, the high-side driving signal V_{GS_H} drives the high-side gallium nitride switch Q1 to turn on, the low-side gallium nitride switch Q2 remains turned off, and the switching node voltage V_{SW} increases to be equal to the input voltage VIN in the case that the channel voltage drop when the high-side gallium nitride switch Q1 is conducting is ignored.

In the buck gallium nitride switching circuit of the present application, during the dead time, the high-side gallium nitride switch Q1 and the low-side gallium nitride switch Q2 are turned off, and the buck gallium nitride switching circuit adopts the conducting reverse channel of the low-side gallium nitride switch Q2 to freewheel the inductor current. In the buck gallium nitride switching circuit of the present application, the first switching transistor 308 is turned on and turned off synchronously with the low-side gallium nitride switch Q2. When the low-side gallium nitride switch Q2 is turned on, the first switching transistor 308 is turned on synchronously. When the low-side gallium nitride switch Q2 is turned off, the first switching transistor 308 is turned off synchronously, and the charging path of the power supply voltage VDD to the capacitor C is blocked. Therefore, when the low-side gallium nitride switch Q2 freewheels, the power supply voltage VDD stops charging the capacitor C, thereby avoiding the situation that the gate driving voltage of the gallium nitride switch is greater than the power supply voltage VDD. Meanwhile, the power supply voltage VDD charges the capacitor C through the first switching transistor 308 and the second switching transistor 309, thereby reducing the on-resistance of the charging path at the greatest extent and increasing the value of the high-side voltage Vboot.

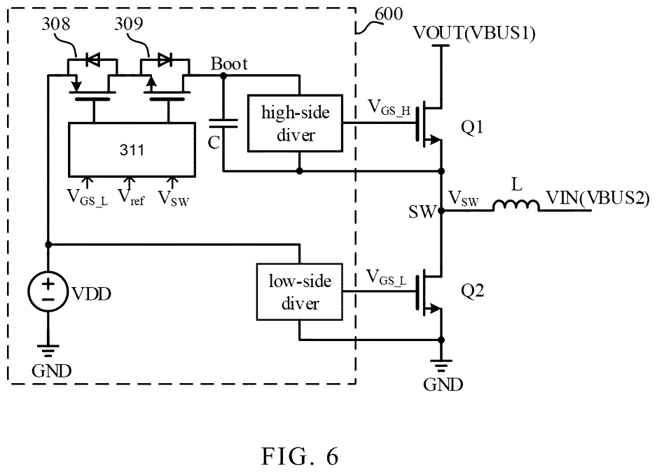

FIG. 6 is a circuit schematic diagram of a boost gallium nitride switching circuit according to an embodiment of the present application. In the embodiment shown in FIG. 6, the driving circuit 600 converts the input voltage VIN into the output voltage VOUT by controlling on and off of the high-side gallium nitride switch Q1 and the low-side gallium nitride switch Q2, where the output voltage VOUT is greater than the input voltage VIN. In an embodiment, the tolerance voltage of the first switching transistor 308 is in a range from 5V to 10V, and the tolerance voltage of the second switching transistor 309 is greater than the output voltage VOUT (the first bus voltage VBUS1).

The boost gallium nitride switching circuit shown in FIG. 6 can solve the problem of reverse feeding of the high-side voltage Vboot to the power supply voltage VDD caused by the need for a certain time for the switching node voltage Vsw to drop in the existing driving circuit. During the dead time of the boost gallium nitride switching circuit, the reverse channel of the high-side gallium nitride switch Q1 is turned on to freewheel the inductor current, and the switching node voltage V_{SW} is generally approximately equal to the output voltage VOUT. In the present application, by detecting the switching node voltage V_{SW} and turning off the second switching transistor 309 when the switching node voltage V_{SW} is greater than the reference voltage V_{ref}, the problem of reverse feeding of the high-side voltage Vboot to the power supply voltage VDD in the existing driving circuit is avoided.

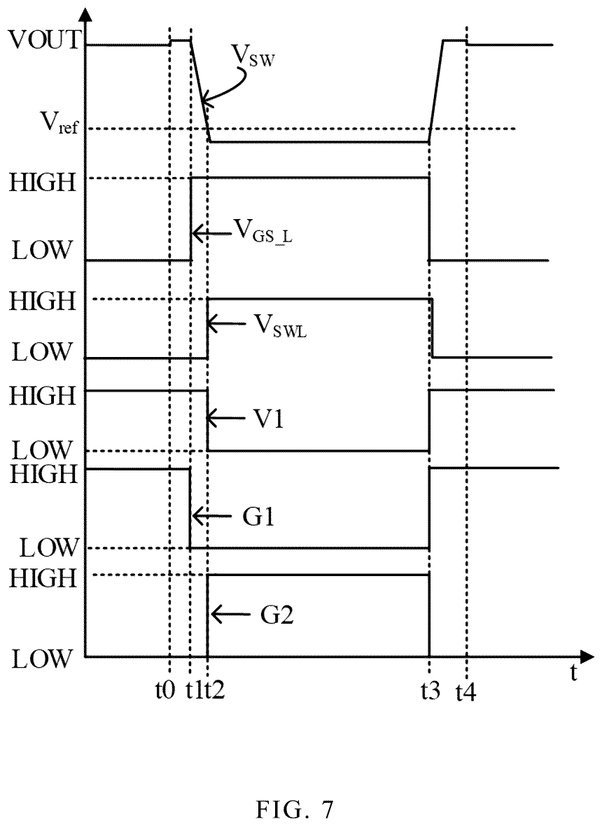

FIG. 7 is a waveform diagram of various signals of the boost gallium nitride switching circuit shown in FIG. 6. The waveforms of various signals in FIG. 7 are explained with reference to the circuit of the boost topology structure shown in FIG. 6.

Before time to, the low-side driving signal V_{GS_L} is at a low level, the low-side gallium nitride switch Q2 remains turned off, the high-side driving signal V_{GS_H} is at a high level, the high-side gallium nitride switch Q1 is turned on, the first control signal G1 is at a high level, and the first switching transistor 308 is turned off. At this time, the switching node voltage V_{SW} (ignoring the on-voltage when the high-side gallium nitride switch Q1 is turned on) is equal to the output voltage VOUT, which is greater than the reference voltage V_{ref}, so that the second control signal G2 is at a low level, and the second switching transistor 309 is turned off.

During the period from time t0 to time t1, the high-side gallium nitride switch Q1 is turned off, the reverse channel of the high-side gallium nitride switch Q1 is turned on to freewheel the inductor current, and the switching node voltage V_{SW} is slightly higher than the output voltage VOUT.

At time t1, the low-side driving signal Vos L switches to high level, so that the first control signal G1 switches to low level, and the first switching transistor 308 is turned on. At this time, the switching node voltage V_{SW} gradually decreases, and since the switching node voltage V_{SW} is greater than the reference voltage V_{ref} at this time, the second control signal G2 is at a low level, and the second switching transistor 309 is turned off.

At time t2, the switching node voltage V_{SW} drops below the reference voltage V_{ref}, both the comparison signal V_{SWL} and the low-side driving signal V_{GS_L} are at high level, the first signal V₁ is at low level, the second control signal G2 switches from low level to high level, the second switching transistor 309 is turned on, and the charging loop for the power supply voltage VDD to charge the capacitor C is turned on.

During the period from time t2 to time t3, the power supply voltage VDD continuously charges the capacitor C.

At time t3, the low-side driving signal V_{GS_L} switches to low level, and the low-side gallium nitride switch Q2 is turned off. Correspondingly, the first control signal G1 switches from low level to high level, and the first switching transistor 308 is turned off. The first signal V₁ switches to high level, the second control signal G2 is at low level, and the second switching transistor 309 is turned off. After this time, the switching node voltage Vsw gradually increases to be slightly higher than the output voltage VOUT.

After time t4, the low-side driving signal V_{GS_L} is at a low level, the low-side gallium nitride switch Q2 remains turned off, and the high-side driving signal V_{GS_H} drives the high-side gallium nitride switch Q1 to turn on. Since the low-side driving signal V_{GS_L} is at a low level, the first control signal G1 is at a high level, the first switching transistor 308 is turned off, the second control signal G2 is at a low level, and the second switching transistor 309 is turned off.

In the boost gallium nitride switching circuit of the present application, the switching node voltage V_{SW} is the output voltage VOUT during the dead time. When the low-side gallium nitride switch Q2 is turned on, due to the time required for the switching node voltage V_{SW} to drop, the high-side voltage Vboot is the sum of the switching node voltage V_{SW} and the power supply voltage VDD. At this time, since the switching node voltage V_{SW} is higher than the preset reference voltage V_{ref}, the second switching transistor 309 is still in the turn-off state; even if the first switching transistor 308 is turned on by timing control, the body diode of the second switching transistor 309 can achieve reverse blocking, thereby preventing reverse feeding of the high-side voltage Vboot to the power supply voltage VDD. In some embodiments, the reference voltage V_{ref} is in a range from 2V to 3V.

The method for preventing reverse feeding of the high-side voltage Vboot to the power supply voltage VDD according to the value of the switching node voltage V_{SW} and the boost gallium nitride switching circuit provided by the present application, prevent reverse feeding of the power supply voltage VDD, and since the comparison between the switching node voltage V_{SW} and the reference voltage V_{ref} is only used to control on or off of the second switching transistor 309, without control of on or off of the first switching transistor 308, the effective time for charging the capacitor C can be maximized. In high-frequency power supply application systems where gallium nitride switches are used, the safety, efficiency, and performance of applications are improved.

The charging path for the capacitor C provided by the present application charges through channels of the first switching transistor 308 and the second switching transistor 309. Since the on-voltage of the first switching transistor 308 and the second switching transistor 309 is less than the voltage drop of the existing diode, the high-side voltage Vboot is closer to the power supply voltage VDD, and the charging efficiency is higher.

In addition, the driving circuit provided by the present application is conducive to integration inside a chip. The first switching transistor 308 can be a low-voltage MOS device, and the second switching transistor 309 can be a high-voltage MOS device. By adjusting the on-resistance of the first switching transistor 308 and the second switching transistor 309, the resistance of the charging loop of the driving circuit can be adjusted.

The present application further provides a gallium nitride switching circuit, including the above-mentioned driving circuit. The gallium nitride switching circuit further includes a high-side gallium nitride switch Q1, a low-side gallium nitride switch Q2, and an inductor L. The high-side gallium nitride switch Q1 has a source terminal, a drain terminal, and a gate terminal; the low-side gallium nitride switch Q2 has a source terminal, a drain terminal, and a gate terminal, where the drain terminal of the low-side gallium nitride switch is coupled to the source terminal of the high-side gallium nitride switch Q1; one terminal of the inductor L is coupled to the common terminal SW of the high-side gallium nitride switch and the low-side gallium nitride switch.

In some embodiments, according to the connection relationship between the gallium nitride switching circuit and a post-stage load, the low-side gallium nitride switch Q2 and the inductor L form a buck circuit.

In some embodiments, according to the connection relationship between the gallium nitride switching circuit and the post-stage load, the high-side gallium nitride switch Q1, the low-side gallium nitride switch Q2, and the inductor L form a boost circuit.

In some embodiments, the high-side gallium nitride switch Q1 is an N-type field-effect transistor.

The above embodiments are only used to illustrate the technical solutions of the present application, not to limit them; although the present application has been described in detail with reference to the foregoing embodiments, those of ordinary skill in the art should understand that: they can still modify the technical solutions described in the foregoing embodiments, or equivalently replace some of the technical features; and these modifications or replacements do not make the essence of the corresponding technical solutions deviate from the spirit and scope of the technical solutions of the embodiments of the present application, and all of them should be included in the protection scope of the present application.

What is claimed is:

1. A driving circuit for a gallium nitride switching circuit, wherein the gallium nitride switching circuit comprises a high-side gallium nitride switch and a low-side gallium nitride switch, and the driving circuit is configured to provide a high-side driving signal and a low-side driving signal to respectively control on and off of the high-side gallium nitride switch and the low-side gallium nitride switch to convert an input voltage into an output voltage, wherein the driving circuit comprising:
a first switching transistor, having a first terminal, a second terminal, and a control terminal, wherein the first terminal of the first switching transistor is configured to receive a power supply voltage, the control terminal of the first switching transistor is configured to receive a first control signal, and the first switching transistor is turned on or turned off based on the first control signal;
a second switching transistor, having a first terminal, a second terminal, and a control terminal, wherein the first terminal of the second switching transistor is coupled to the second terminal of the first switching transistor, the control terminal of the second switching transistor is configured to receive a second control signal, and the second switching transistor is turned on or turned off based on the second control signal; and
a capacitor, having a first terminal and a second terminal, wherein the first terminal of the capacitor is coupled to the second terminal of the second switching transistor, the second terminal of the capacitor is coupled to a common terminal of the high-side gallium nitride switch and the low-side gallium nitride switch, and a voltage at the common terminal of the high-side gallium nitride switch and the low-side gallium nitride switch is a switching node voltage;
wherein when the low-side driving signal is at a low level, the first switching transistor is turned off;
when the low-side driving signal is at a high level, the first switching transistor is turned on; and
when the low-side driving signal is at the high level and the switching node voltage is less than a reference voltage, the second switching transistor is turned on.

2. The driving circuit according to claim 1, wherein the first switching transistor is a P-type field-effect transistor, and the second switching transistor is an N-type field-effect transistor.

3. The driving circuit according to claim 1, further comprising:
a charging control circuit, configured to receive the reference voltage, the switching node voltage, and the low-side driving signal, and to generate the first control signal and the second control signal according to the reference voltage, the switching node voltage, and the low-side driving signal to respectively control on and off of the first switching transistor and the second switching transistor.

4. The driving circuit according to claim 3, wherein the charging control circuit comprises:
a comparison circuit, having a first input terminal configured to receive the reference voltage, a second input terminal configured to receive the switching node voltage, and an output terminal configured to provide a comparison signal, wherein the comparison circuit is configured to generate the comparison signal according to the reference voltage and the switching node voltage;
a logic circuit, having a first input terminal configured to receive the comparison signal, a second input terminal configured to receive the low-side driving signal, wherein the logic circuit is configured to generate a first signal according to the comparison signal and the low-side driving signal;
a first inverter, having an input terminal configured to receive the first signal, and an output terminal configured to provide the second control signal; and
a second inverter, having an input terminal configured to receive the low-side driving signal, and an output terminal configured to provide the first control signal.

5. The driving circuit according to claim 1, wherein the reference voltage is in a range from 2V to 3V.

6. The driving circuit according to claim 1, wherein the output voltage is less than the input voltage, a tolerance voltage of the first switching transistor is in a range from 5V to 10V, and a tolerance voltage of the second switching transistor is greater than the input voltage.

7. The driving circuit according to claim 1, wherein the output voltage is greater than the input voltage, a tolerance voltage of the first switching transistor is in a range from 5V to 10V, and a tolerance voltage of the second switching transistor is greater than the output voltage.

8. The driving circuit according to claim 1, wherein the first switching transistor is turned on and turned off synchronously with the low-side gallium nitride switch.

9. A gallium nitride switching circuit, comprising:
a high-side gallium nitride switch, having a source terminal, a drain terminal, and a gate terminal;
a low-side gallium nitride switch, having a source terminal, a drain terminal, and a gate terminal, wherein the drain terminal of the low-side gallium nitride switch is coupled to the source terminal of the high-side gallium nitride switch;
an inductor, wherein one terminal of the inductor is coupled to a common terminal of the high-side gallium nitride switch and the low-side gallium nitride switch; and
a driving circuit, comprising:
a first switching transistor, having a first terminal, a second terminal, and a control terminal, wherein the first terminal of the first switching transistor is configured to receive a power supply voltage, the control terminal of the first switching transistor is configured to receive a first control signal, and the first switching transistor is turned on or turned off based on the first control signal;
a second switching transistor, having a first terminal, a second terminal, and a control terminal, wherein the first terminal of the second switching transistor is coupled to the second terminal of the first switching transistor, the control terminal of the second switching transistor is configured to receive a second control signal, and the second switching transistor is turned on or turned off based on the second control signal; and
a capacitor, having a first terminal and a second terminal, wherein the first terminal of the capacitor is coupled to the second terminal of the second switching transistor, the second terminal of the capacitor is coupled to a common terminal of the high-side gallium nitride switch and the low-side gallium nitride switch, and a voltage at the common terminal of the high-side gallium nitride switch and the low-side gallium nitride switch is a switching node voltage;
wherein when the low-side driving signal is at a low level, the first switching transistor is turned off;
when the low-side driving signal is at a high level, the first switching transistor is turned on; and
when the low-side driving signal is at a high level and the switching node voltage is less than a reference voltage, the second switching transistor is turned on.

10. The gallium nitride switching circuit according to claim 9, wherein the first switching transistor is a P-type field-effect transistor, and the second switching transistor is an N-type field-effect transistor.

11. The gallium nitride switching circuit according to claim 9, further comprising:
a charging control circuit, configured to receive the reference voltage, the switching node voltage, and the low-side driving signal, and generate the first control signal and the second control signal according to the reference voltage, the switching node voltage, and the low-side driving signal to respectively control on and off of the first switching transistor and the second switching transistor.

12. The gallium nitride switching circuit according to claim 11, wherein the charging control circuit comprises:
a comparison circuit, having a first input terminal configured to receive the reference voltage, a second input terminal configured to receive the switching node voltage, and an output terminal configured to provide a comparison signal, wherein the comparison circuit is configured to generate the comparison signal according to the reference voltage and the switching node voltage;
a logic circuit, having a first input terminal configured to receive the comparison signal, a second input terminal configured to receive the low-side driving signal, wherein the logic circuit is configured to generate a first signal according to the comparison signal and the low-side driving signal;
a first inverter, having an input terminal configured to receive the first signal, and an output terminal configured to provide the second control signal; and
a second inverter, having an input terminal configured to receive the low-side driving signal, and an output terminal configured to provide the first control signal.

13. The gallium nitride switching circuit according to claim 9, wherein the reference voltage is in a range from 2V to 3V.

14. The gallium nitride switching circuit according to claim 9, wherein the output voltage is less than the input voltage, a tolerance voltage of the first switching transistor is in a range from 5V to 10V, and a tolerance voltage of the second switching transistor is greater than the input voltage.

15. The gallium nitride switching circuit according to claim 9, wherein the output voltage is greater than the input voltage, a tolerance voltage of the first switching transistor is in a range from 5V to 10V, and a tolerance voltage of the second switching transistor is greater than the output voltage.

16. The gallium nitride switching circuit according to claim 9, wherein the first switching transistor is turned on and turned off synchronously with the low-side gallium nitride switch.

17. The gallium nitride switching circuit according to claim 9, wherein a buck circuit is formed by the low-side gallium nitride switch and the inductor.

18. The gallium nitride switching circuit according to claim 9, wherein a boost circuit is formed by the high-side gallium nitride switch, the low-side gallium nitride switch, and the inductor.

19. The gallium nitride switching circuit according to claim 9, wherein the high-side gallium nitride switch is an N-type field-effect transistor.
